(19) United States
(12) Patent Application Publication
(10) Pub. No.: US 2024/0222347 A1
(43) Pub. Date: Jul. 4, 2024

(54) MODULAR MEMORY BLOCKS FOR INTEGRATED CIRCUIT DEVICES

(71) Applicant: Intel Corporation, Santa Clara, CA (US)

(72) Inventors: Sagar Suthram, Portland, OR (US); Kuljit S. Bains, Olympia, WA (US); Wilfred Gomes, Portland, OR (US); Don Douglas Josephson, Fort Collins, CO (US); Surhud V. Khare, Buffalo, NY (US); Christopher Philip Mozak, Portland, OR (US); Randy B. Osborne, Beaverton, OR (US); Pushkar Ranade, San Jose, CA (US); Abhishek Anil Sharma, Portland, OR (US)

(73) Assignee: Intel Corporation, Santa Clara, CA (US)

(21) Appl. No.: 18/148,338

(22) Filed: Dec. 29, 2022

(51) Int. Cl. H01L 25/18; H01L 23/00; H01L 23/48; H10B 80/00

(52) U.S. Cl. CPC H01L 25/18; H01L 23/481; H01L 24/16; H10B 80/00; H01L 2224/16145; H01L 2225/06513; H01L 2225/06541

(57) ABSTRACT

In embodiments herein, an integrated circuit device includes a logic die with processor circuitry and a memory die coupled to the logic die. The memory die includes a first memory module comprising a first memory bank and first control circuitry, a second memory module comprising a second memory bank and second control circuitry, and a scribe line on a surface of the memory die between the first memory module and the second memory module. The first memory module is not electrically connected to the second memory module, and each memory module include through silicon vias (TSVs) to electrically connect a top side of the memory module and a bottom side of the memory module (e.g., for three-dimensional stacking in the integrated circuit device).

### BACKGROUND

Currently, memory vendors manufacture different memory dies for different memory designs and/or for different memory sizes/capacities. Thus, a vendor may have a completely different die design, and thus, a different wafer manufacturing process (and/or materials) for an 8 GB memory module vs. a 16 GB memory module. These different designs and manufacturing processes may result in more optimal designs (e.g., in terms of smaller die areas, etc.) for each respective module; however, the different designs also require additional time, money, and/or other resources to design and implement.

### BRIEF DESCRIPTION OF THE DRAWINGS

FIG. 1 illustrates a top view of a wafer that includes memory module dies that may be implemented as memory in different integrated circuit device architectures in accordance with embodiments of the present disclosure.

FIG. 2 illustrates a top view of a set of two memory dies in accordance with embodiments herein.

FIGS. 3A-3C illustrate example three-dimensional integrated circuit chip architectures that may incorporate embodiments of the present disclosure.

FIG. 4 illustrates an example system that may incorporate embodiments of the present disclosure.

FIG. 5 illustrates an example process of implementing a modular memory block design for integrated circuit devices in accordance with embodiments herein.

FIG. 6 is a cross-sectional side view of an integrated circuit device that may include any of the embodiments disclosed herein.

FIG. 7 is a cross-sectional side view of an integrated circuit device assembly that may include any of the embodiments disclosed herein.

FIG. 8 is a block diagram of an example electrical device that may include any of the embodiments disclosed herein.

FIG. 9 is a block diagram of an example zetta-scale electrical device that may include any of the embodiments disclosed herein.

FIG. 10 is a block diagram of an example zetta-scale processing device that may include any of the embodiments disclosed herein.

### DETAILED DESCRIPTION

Embodiments herein provide a modular memory building block architecture wherein a wafer is manufactured with multiple tiled memory modules that can provide scalable memory needs for a variety of integrated circuit devices, such as processors. The underlying memory module may be designed to serve as a building block that can be used either as a single memory module or in an array of memory modules to implement different memory capacities that may be needed by an integrated circuit device. This can allow for the de-coupling of memory macro needs from the needs of integrated circuit device construction and can enable a scalable solution that can be utilized across different integrated circuit devices with different memory size requirements. Further, aspects herein can be implemented with different types of underlying memory technologies, e.g., dynamic random-access memory (DRAM), static RAM (SRAM), magnetic RAM (MRAM), resistive RAM (RRAM), conductive-bridging RAM (CBRAM), etc. Embodiments herein may accordingly provide an architecture that allows for scalable, commodity memory that can be used in a variety of different applications.

Currently, memory vendors manufacture different memory dies for different memory designs and/or for different memory sizes/capacities. Thus, a vendor may have a completely different die design, and thus, a different wafer manufacturing process (and/or materials), for an 8 GB memory module vs. a 16 GB memory module. These different designs and manufacturing processes may result in more optimal designs (e.g., in terms of smaller die areas, etc.) for each respective module; however, the different designs also require additional time, money, and/or other resources to design and implement. Further, to utilize multiple of these memory chips within an integrated circuit device, multiple attachment steps will be needed, i.e., one for each memory chip, adding to the fabrication complexity and costs.

In contrast, with embodiments herein, a single memory module design may be implemented for use in both of the 8 GB and 16 GB use cases described above. For example, a wafer may be manufactured by a memory vendor that includes 4 GB modules. The modules may be separated by scribe lines on the wafer and may be approximately 20-150 mm² in area each. The memory vendor may need only manufacture a single type of wafer for an integrated circuit device designer/manufacturer, who can then in turn singulate the memory modules of the wafer into single dies or die arrays to implement memory of different capacities. For instance, to implement the 8 GB module use case described above, two 4 GB modules of the wafer may be used. Likewise, to implement the 16 GB use case, four 4 GB modules of the same wafer may be used. That is, the modules for each of the 8 GB and 16 GB (and other size) use cases may be taken from the same wafer with the 4 GB memory module design. This can allow for modular designs, whereby the memory modules can be used with different IC chip designs with different memory capacity needs. In addition, fabrication of such devices may be simplified as only a single attach step may be needed to attach larger dies that include multiple memory modules therein.

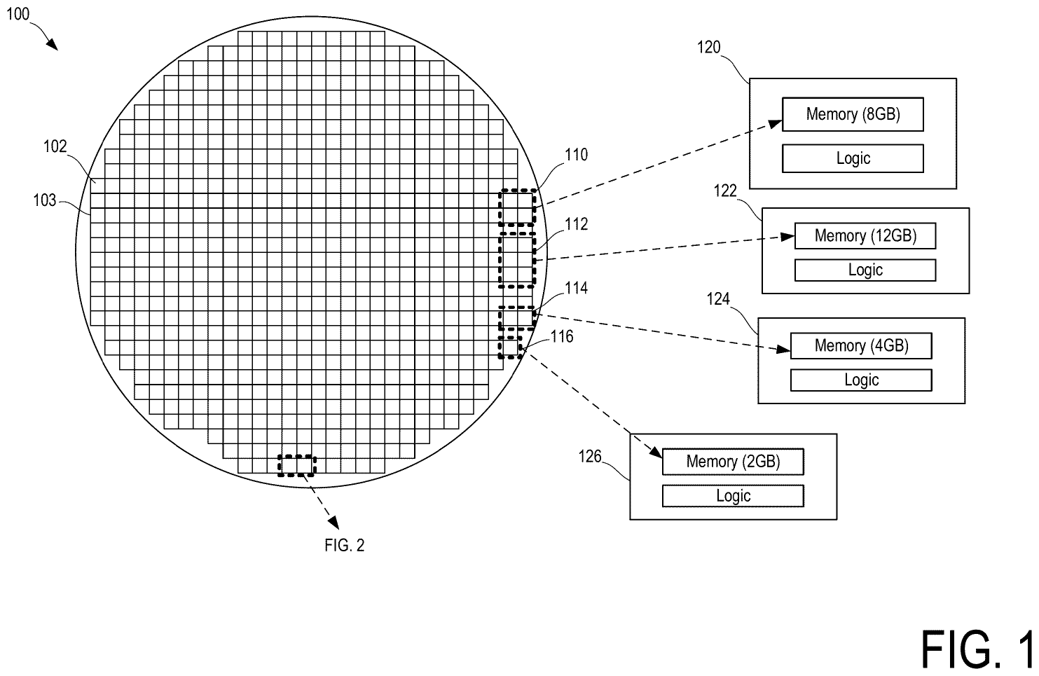

FIG. 1 illustrates a top view of a wafer 100 that includes memory module dies 102 that may be implemented as memory in different integrated circuit device architectures 120, 122, 124, 126 in accordance with embodiments of the present disclosure. The wafer 100 may be composed of semiconductor material and may include dies 102 with memory circuitry (e.g., memory banks and memory control logic circuitry) formed on a surface of the wafer 100. The individual dies 102 may be a repeating unit of a memory module as described above. Each of the dies 102 may implement the same type of memory device, which may be, e.g., a random-access memory (RAM) device, such as a static RAM (SRAM) device, a magnetic RAM (MRAM) device, a resistive RAM (RRAM) device, a conductive-bridging RAM (CBRAM) device, etc.

As described above, each of the individual dies 102 may implement the same modular memory design that can be used either alone or as part of an array of multiple dies 102 to implement a larger memory capacity. Thus, after the fabrication of the wafer 100 is complete, it may undergo a singulation/cutting process in which the dies 102 are separated to provide discrete memory “chips” that may be implemented in integrated circuit devices, such as processors. The dies 102 may be cut in different sizes to implement memory chips with different capacities, e.g., for different applications.

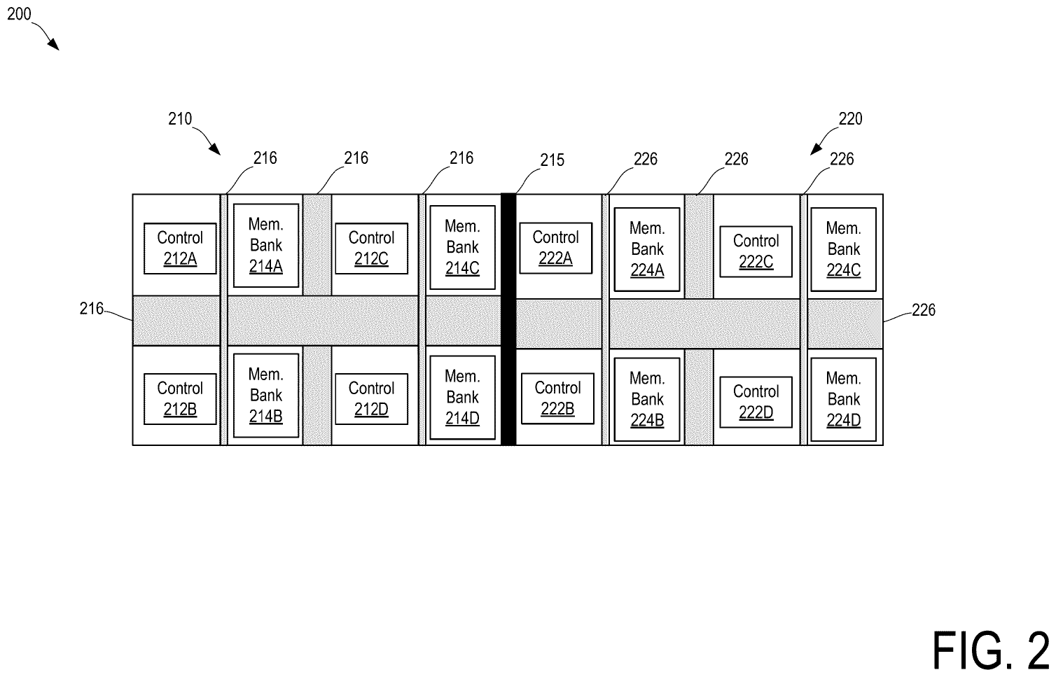

The cutting may be performed based on scribe lines 103 on the wafer 100 that indicate/logically separate the different dies 102. For instance, the singulation/cutting apparatus may detect the scribe lines 103 on the wafer 100 and cut along the scribe lines 103, as needed. In instances where multiple dies 102 are needed in an array to implement a larger memory chip, scribe lines 103 may still be present on the cut array of dies 102, e.g., as shown in FIG. 2. The scribe lines 103 may also be referred to as “kerfs” or “saw streets” in some instances. The scribe lines 103 may be implemented in any suitable manner that allows a singulation machine to distinguish between the dies 102 of the wafer 100 and/or to indicate to the machine where to place a saw or other cutting apparatus when cutting the dies from the wafer. For instance, the scribe lines 103 may be implemented with markings and/or indentations on the surface of the wafer 100. The width of the scribe lines 103 may be approximately 50-150 um, in certain instances.

For instance, in the example shown, the wafer 100 includes a plurality of dies 102 that each implement a 2 GB memory module. Thus, a first set 110 of four dies 102 may be cut from the wafer 100 to implement an 8 GB memory chip for use in a first integrated circuit architecture 120, a second set 112 of six dies 102 may be cut from the wafer 100 to implement an 12 GB memory chip for use in a second integrated circuit architecture 122, a third set 114 of two dies 102 may be cut from the wafer 100 to implement a 4 GB memory chip for use in a third integrated circuit architecture 124, and a fourth first set 116 of one die 102 may be cut from the wafer 100 to implement a 2 GB memory chip for use in a fourth integrated circuit architecture 126.

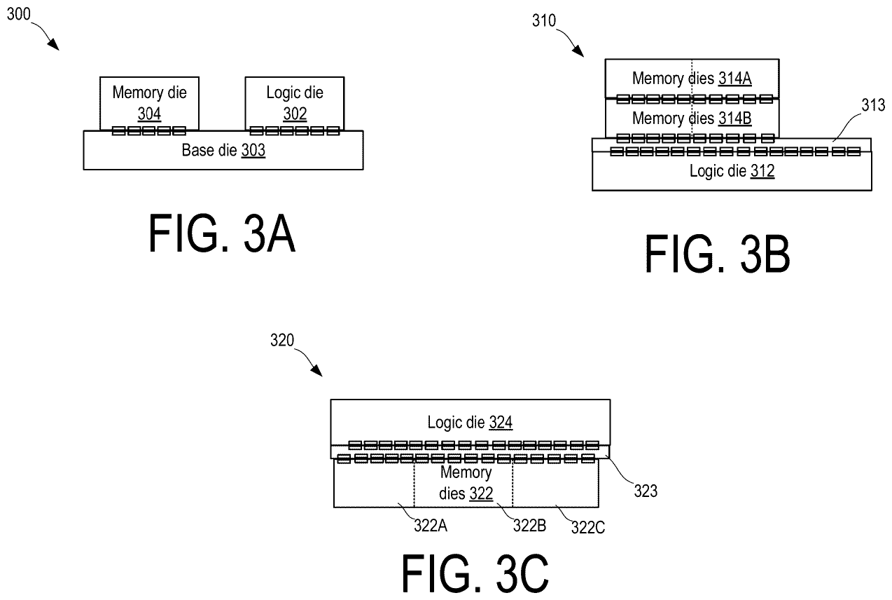

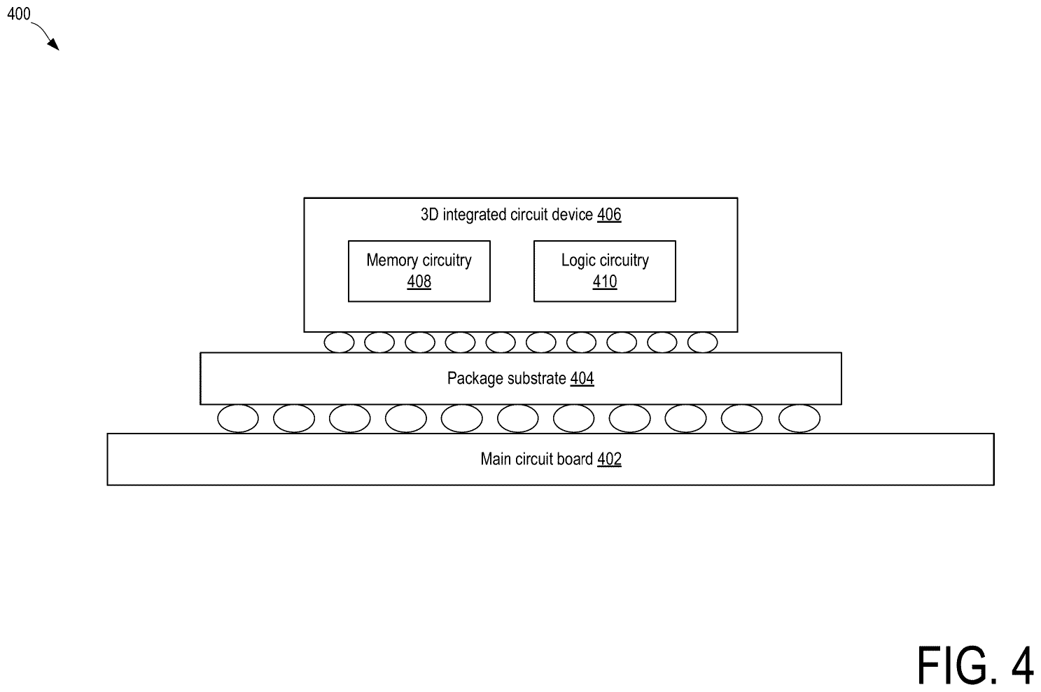

FIG. 2 illustrates a top view of a set 200 of two memory dies 210, 220 in accordance with embodiments herein. The memory dies 210, 220 may represent a set of two dies that have been cut away from a wafer (e.g., 100) comprising multiple other dies that are the same as the dies, for incorporation into a three-dimensional integrated circuit chip architecture, e.g., those shown in FIGS. 3-4 and described further below. As used herein, a three-dimensional integrated circuit chip architecture or a three-dimensional integrated circuit device may refer to an apparatus comprising multiple dies that are coupled to one another in a three-dimensional stack configuration, such as those shown in FIGS. 3A-3C.

Each of the dies 210, 220 may be capable of functioning on their own, as described above. Thus, the dies 210, 220 in the example shown include independent circuitry from one another, i.e., the memory banks and control circuitries of the respective dies 210, 220 are not electrically connected with one another. However, the memory banks and control circuitries within each die 210, 220 are designed to function as a singular memory module and thus, may be electrically connected with one another.

In the example shown, each of the dies 210, 220 includes four quadrants (A, B, C, D) that each include a respective memory bank (214, 224) and control logic circuitry (212, 222) for the memory bank in the quadrant. The dies also include through silicon vias (TSVs) 216 that provide electrical connections to the control circuitry and the memory banks of the dies, e.g., for power and signal delivery to/from the control circuitry and/or the memory banks. The TSVs may be formed from metal or another type of conductive material, and may be accessible on both the top and the bottom sides of the dies 210, 220 as to enable 3D stacking with other dies (e.g., dies comprising logic circuitry and/or memory circuitry (e.g., other memory dies similar to the dies 210, 220)) in a 3D integrated circuit chip architecture, e.g., as shown in FIGS. 3A-3C. For instance, the TSVs may allow another die to connect to the control circuitry and memory banks from the top and/or the bottom of the dies 210, 220. In certain embodiments, the TSVs may be formed in a grid pattern, similar to the one shown to allow for multiple connections within the dies. Furthermore, because the set 200 includes two dies 210, 220, the set 200 also includes a scribe line 215 between the dies 210, 220, which may be implemented in the same or similar manner as the scribe lines 103 of FIG. 1.

FIGS. 3A-3C illustrate example three-dimensional (3D) integrated circuit chip architectures 300, 310, 320 that may incorporate embodiments of the present disclosure. Each of the architectures shown may be incorporated into an integrated circuit apparatus, e.g., through attachment to an integrated circuit package substrate as shown in FIG. 4 and described further below. While certain examples are shown, other 3D chip architectures may implement aspects of the present disclosure, e.g., architectures that include a combination of aspects shown in the different examples of FIGS. 3A-3C.

In the example shown in FIG. 3A, the 3D chip architecture 300 includes a base die 303 with a logic die 302 and memory die 304 attached to the base die 303. The memory die 304 may be formed from a single memory module die (e.g., one similar to a die 102 of FIG. 1). In the example shown, the memory die 304 is indicated to include one memory module die, but in other instances, may include multiple memory module dies from a wafer, e.g., similar to the set 200 of dies shown in FIG. 2. The logic die 312 may include processing circuitry, and may be implemented, for example, a system-on-a-chip (SoC), processor core, graphics processor unit (GPU), accelerator, chipset processor, or another type of processor logic circuit. The base die 303 may include active interposer circuitry with interconnections between the logic die 302 and the memory die 304. The base die 303 may include other components or circuitry as well, e.g., voltage regulation circuitry, TSVs, etc. Further, in certain embodiments, the architecture 300 may include other dies attached to the base die 303 than those shown, e.g., on the top side (i.e., the same side as dies 302, 303) or the bottom side of the base die 303.

In the example shown in FIG. 3B, the 3D chip architecture 310 includes a base logic die 312 connected to two sets of memory dies 314A, 314B via an interposer 313. The logic die 312 may be implemented as a system-on-a-chip (SoC), processor core, graphics processor unit (GPU), accelerator, chipset processor, or another type of logic circuit, and the interposer 313 may be implemented as a passive or active interposer with circuitry to interconnect the logic die 312 and the memory dies 314. The memory dies 314 shown are formed from two memory module dies each (indicated by the dotted line in each die 314A, 314B), similar to the set 200 of FIG. 2. Thus, each of the dies 314 may include a scribe line similar to the scribe line 215 of FIG. 2 that separates the two memory module dies within the dies 314. However, in other embodiments, the memory dies 314 may be formed from any number of memory module dies as described herein. As shown, the memory dies 314 are stacked on one another, with die 314A stacked on die 314B. The memory dies 314 may be implemented in the same manner as one another and may include TSVs (e.g., as described with respect to FIG. 2) that align with one another to allow for the stacking of the dies 314 as shown, i.e., to allow for power and signal routing between the logic die 312 and the memory dies 314. In certain embodiments, other dies may be included in the architecture 310, e.g., additional logic or memory dies attached to the bottom and/or top sides of the logic die 312 (e.g., on the top side through the interposer 313).

In the example shown in FIG. 3C, the 3D chip architecture 320 includes a logic die 324 attached to a set of memory dies 322 via an interposer 323. The logic die 324 may be implemented in the same or similar manner as the logic die 312 and the interposer 323 may be implemented in the same or similar manner as the interposer 313. The set of memory dies 322 includes three memory module dies 322A, 322B, 322C (indicated by the dotted lines), which may each be similar to the dies 102 of FIG. 1. Thus, like the dies 314, the set of dies 322 may include scribe lines similar to the scribe line 215 of FIG. 2 that separates the three memory module dies. However, in other embodiments, the memory die 324 may be formed from any number of memory module dies as described herein. In certain embodiments, other dies may be included in the architecture 320, e.g., additional logic or memory dies attached to the bottom and/or top sides of the logic die 324 (e.g., on the top side through the interposer 323).

FIG. 4 illustrates an example system 400 that may incorporate embodiments of the present disclosure. The example system 400 includes a main circuit board 402, which may be implemented as a motherboard or main board of a computer system in some embodiments. The example system 400 also includes a package substrate 404 with a three-dimensional (3D) integrated circuit device 406 attached to the package substrate 404. The device 406 includes logic circuitry 410, which may be implemented as a system-on-a-chip (SoC), processor core, graphics processor unit (GPU), accelerator, chipset processor, or another type of logic circuit, and memory circuitry 408, which may be implemented by a set of memory module dies as described herein. The device 406 may be implemented as shown in any one of FIGS. 3A-3C, or in a different 3D stacked architecture. The device 406 may also include I/O controller, network interface controller, or other types of circuitry or components in addition to the memory circuitry 408 and logic circuitry 410. For instance, the device 406 can comprise one or more active or passive devices such as capacitors, decoupling capacitors, resistors, inductors, fuses, diodes, transformers, sensors, electrostatic discharge (ESD) devices, and memory devices. The package substrate 404 may provide electrical connections between the device 406 and the circuit board 402.

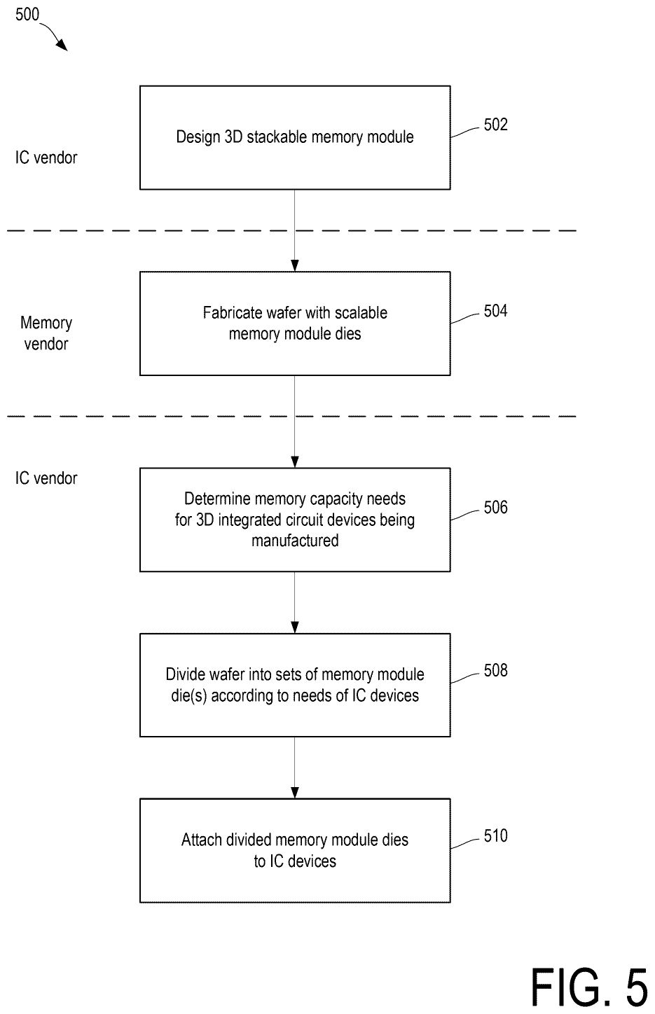

FIG. 5 illustrates an example process 500 of implementing a modular memory block design for integrated circuit devices in accordance with embodiments herein. The example process shown may include additional, fewer, or different operations than those shown or described below, and in some embodiments, one or more of the operations shown may include multiple operations, sub-operations, etc. Some or all operations of the example process may be performed by fabrication equipment that is programmed to perform the operations. At 502, an integrated circuit (IC) device vendor designs a 3D-stackable memory module circuit. The design may enable aspects of the present disclosure, i.e., use of multiple memory modules together to implement a memory die with larger capacity as described above. At 504, a memory chip vendor manufactures wafers with memory chip modules (e.g., similar to the wafer 100 of FIG. 1) as described herein and provides the wafers to the IC device vendor, who can then, at 506, determine memory capacity needs for its chip designs and divide the wafer into sets of memory module dies according to those needs at 508 and attach the memory module dies to the respective IC devices at 510.

For instance, the IC vendor may determine that a first IC device design (e.g., for a mobile computing platform or other type of computing platform that has a relatively small amount of compute power) is to include a first memory die with a first memory capacity and divide a wafer (e.g., 100) comprising a plurality of memory modules (e.g., 102) to yield a first memory die that includes a first subset of the memory modules, wherein the subset of memory modules of the cut memory die has a memory capacity that is the same as the first memory capacity needed by the first IC device. The IC vendor may then determine that a second IC device design (e.g., for a server platform or other type of computing platform that has a relatively large amount of compute power) is to include a second memory die with a second memory capacity (e.g., larger than the first memory capacity). The IC vendor further divides the wafer to yield a second memory die that includes a second subset of the memory modules (e.g., with more memory modules than the first subset), wherein the second subset of memory modules of the second memory die has a memory capacity that is the same as the second memory capacity needed by the second IC device. Thus, the process 500 may enable simpler, commodity memory module designs that can be incorporated into a number of different integrated circuit chip applications, e.g., as described above.

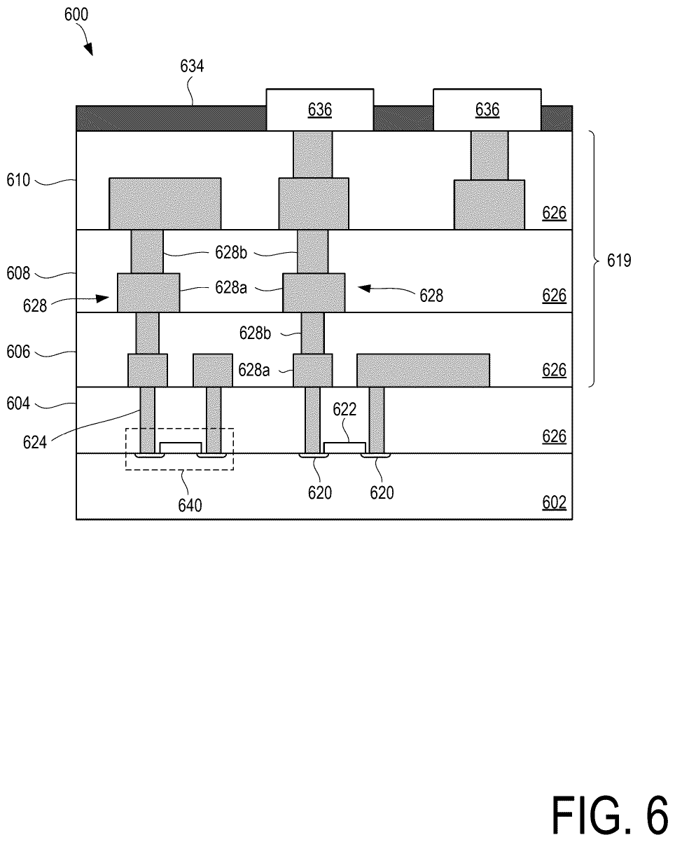

FIG. 6 is a cross-sectional side view of an integrated circuit device 600 that may be included in any of the embodiments disclosed herein. One or more of the integrated circuit devices 600 may be included in one or more dies 102 (FIG. 1). The integrated circuit device 600 may be formed on a die substrate 602 (e.g., the wafer 100 of FIG. 1) and may be included in a die (e.g., the die 102 of FIG. 1). The die substrate 602 may be a semiconductor substrate composed of semiconductor material systems including, for example, n-type or p-type materials systems (or a combination of both). The die substrate 602 may include, for example, a crystalline substrate formed using a bulk silicon or a silicon-on-insulator (SOI) substructure. In some embodiments, the die substrate 602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 602. Although a few examples of materials from which the die substrate 602 may be formed are described here, any material that may serve as a foundation for an integrated circuit device 600 may be used. The die substrate 602 may be part of a singulated die (e.g., the dies 102 of FIG. 1) or a wafer (e.g., the wafer 100 of FIG. 1).

The integrated circuit device 600 may include one or more device layers 604 disposed on the die substrate 602. The device layer 604 may include features of one or more transistors 640 (e.g., metal oxide semiconductor field-effect transistors (MOSFETs)) formed on the die substrate 602. The transistors 640 may include, for example, one or more source and/or drain (S/D) regions 620, a gate 622 to control current flow between the S/D regions 620, and one or more S/D contacts 624 to route electrical signals to/from the S/D regions 620. The transistors 640 may include additional features not depicted for the sake of clarity, such as device isolation regions, gate contacts, and the like. The transistors 640 are not limited to the type and configuration depicted in FIG. 6 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 6, a transistor 640 may include a gate 622 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 640 along the source-channel-drain direction, the gate electrode may consist of a U-shaped structure that includes a bottom portion substantially parallel to the surface of the die substrate 602 and two sidewall portions that are substantially perpendicular to the top surface of the die substrate 602. In other embodiments, at least one of the metal layers that form the gate electrode may simply be a planar layer that is substantially parallel to the top surface of the die substrate 602 and does not include sidewall portions substantially perpendicular to the top surface of the die substrate 602. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 620 may be formed within the die substrate 602 adjacent to the gate 622 of individual transistors 640. The S/D regions 620 may be formed using an implantation/diffusion process or an etching/deposition process, for example. In the former process, dopants such as boron, aluminum, antimony, phosphorous, or arsenic may be ion-implanted into the die substrate 602 to form the S/D regions 620. An annealing process that activates the dopants and causes them to diffuse farther into the die substrate 602 may follow the ion-implantation process. In the latter process, the die substrate 602 may first be etched to form recesses at the locations of the S/D regions 620. An epitaxial deposition process may then be carried out to fill the recesses with material that is used to fabricate the S/D regions 620. In some implementations, the S/D regions 620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 620 may be formed using one or more alternate semiconductor materials such as germanium or a group III-V material or alloy. In further embodiments, one or more layers of metal and/or metal alloys may be used to form the S/D regions 620.

Electrical signals, such as power and/or input/output (I/O) signals, may be routed to and/or from the devices (e.g., transistors 640) of the device layer 604 through one or more interconnect layers disposed on the device layer 604 (illustrated in FIG. 6 as interconnect layers 606-610). For example, electrically conductive features of the device layer 604 (e.g., the gate 622 and the S/D contacts 624) may be electrically coupled with the interconnect structures 628 of the interconnect layers 606-610. The one or more interconnect layers 606-610 may form a metallization stack (also referred to as an “ILD stack”) 619 of the integrated circuit device 600.

The interconnect structures 628 may be arranged within the interconnect layers 606-610 to route electrical signals according to a wide variety of designs; in particular, the arrangement is not limited to the particular configuration of interconnect structures 628 depicted in FIG. 6. Although a particular number of interconnect layers 606-610 is depicted in FIG. 6, embodiments of the present disclosure include integrated circuit devices having more or fewer interconnect layers than depicted.

In some embodiments, the interconnect structures 628 may include lines 628a and/or vias 628b filled with an electrically conductive material such as a metal. The lines 628a may be arranged to route electrical signals in a direction of a plane that is substantially parallel with a surface of the die substrate 602 upon which the device layer 604 is formed. For example, the lines 628a may route electrical signals in a direction in and out of the page and/or in a direction across the page from the perspective of FIG. 6. The vias 628b may be arranged to route electrical signals in a direction of a plane that is substantially perpendicular to the surface of the die substrate 602 upon which the device layer 604 is formed. In some embodiments, the vias 628b may electrically couple lines 628a of different interconnect layers 606-610 together.

The interconnect layers 606-610 may include a dielectric material 626 disposed between the interconnect structures 628, as shown in FIG. 6. In some embodiments, dielectric material 626 disposed between the interconnect structures 628 in different ones of the interconnect layers 606-610 may have different compositions; in other embodiments, the composition of the dielectric material 626 between different interconnect layers 606-610 may be the same. The device layer 604 may include a dielectric material 626 disposed between the transistors 640 and a bottom layer of the metallization stack as well. The dielectric material 626 included in the device layer 604 may have a different composition than the dielectric material 626 included in the interconnect layers 606-610; in other embodiments, the composition of the dielectric material 626 in the device layer 604 may be the same as a dielectric material 626 included in any one of the interconnect layers 606-610.

A first interconnect layer 606 (referred to as Metal 1 or “M1”) may be formed directly on the device layer 604. In some embodiments, the first interconnect layer 606 may include lines 628a and/or vias 628b, as shown. The lines 628a of the first interconnect layer 606 may be coupled with contacts (e.g., the S/D contacts 624) of the device layer 604. The vias 628b of the first interconnect layer 606 may be coupled with the lines 628a of a second interconnect layer 608.

The second interconnect layer 608 (referred to as Metal 2 or “M2”) may be formed directly on the first interconnect layer 606. In some embodiments, the second interconnect layer 608 may include via 628b to couple the lines 628 of the second interconnect layer 608 with the lines 628a of a third interconnect layer 610. Although the lines 628a and the vias 628b are structurally delineated with a line within individual interconnect layers for the sake of clarity, the lines 628a and the vias 628b may be structurally and/or materially contiguous (e.g., simultaneously filled during a dual-damascene process) in some embodiments.

The third interconnect layer 610 (referred to as Metal 3 or “M3”) (and additional interconnect layers, as desired) may be formed in succession on the second interconnect layer 608 according to similar techniques and configurations described in connection with the second interconnect layer 608 or the first interconnect layer 606. In some embodiments, the interconnect layers that are “higher up” in the metallization stack 619 in the integrated circuit device 600 (i.e., farther away from the device layer 604) may be thicker that the interconnect layers that are lower in the metallization stack 619, with lines 628a and vias 628b in the higher interconnect layers being thicker than those in the lower interconnect layers.

The integrated circuit device 600 may include a solder resist material 634 (e.g., polyimide or similar material) and one or more conductive contacts 636 formed on the interconnect layers 606-610. In FIG. 6, the conductive contacts 636 are illustrated as taking the form of bond pads. The conductive contacts 636 may be electrically coupled with the interconnect structures 628 and configured to route the electrical signals of the transistor(s) 640 to external devices. For example, solder bonds may be formed on the one or more conductive contacts 636 to mechanically and/or electrically couple an integrated circuit die including the integrated circuit device 600 with another component (e.g., a printed circuit board). The integrated circuit device 600 may include additional or alternate structures to route the electrical signals from the interconnect layers 606-610; for example, the conductive contacts 636 may include other analogous features (e.g., posts) that route the electrical signals to external components.

In some embodiments in which the integrated circuit device 600 is a double-sided die, the integrated circuit device 600 may include another metallization stack (not shown) on the opposite side of the device layer(s) 604. This metallization stack may include multiple interconnect layers as discussed above with reference to the interconnect layers 606-610, to provide conductive pathways (e.g., including conductive lines and vias) between the device layer(s) 604 and additional conductive contacts (not shown) on the opposite side of the integrated circuit device 600 from the conductive contacts 636.

In other embodiments in which the integrated circuit device 600 is a double-sided die, the integrated circuit device 600 may include one or more through silicon vias (TSVs) through the die substrate 602; these TSVs may make contact with the device layer(s) 604, and may provide conductive pathways between the device layer(s) 604 and additional conductive contacts (not shown) on the opposite side of the integrated circuit device 600 from the conductive contacts 636. In some embodiments, TSVs extending through the substrate can be used for routing power and ground signals from conductive contacts on the opposite side of the integrated circuit device 600 from the conductive contacts 636 to the transistors 640 and any other components integrated into the die 600, and the metallization stack 619 can be used to route I/O signals from the conductive contacts 636 to transistors 640 and any other components integrated into the die 600.

Multiple integrated circuit devices 600 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

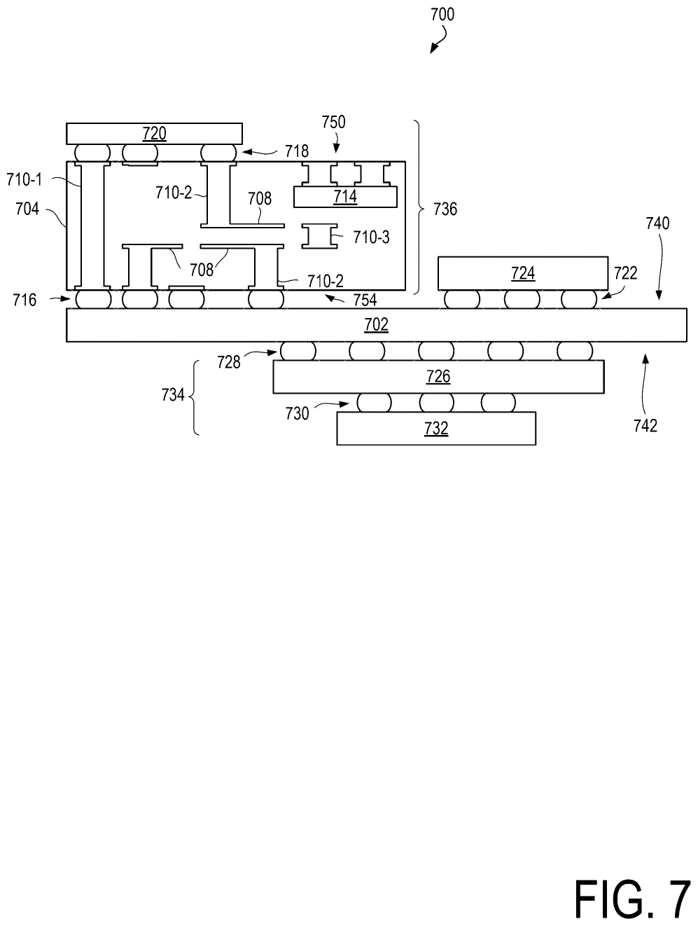

FIG. 7 is a cross-sectional side view of an integrated circuit device assembly 700 that may include any of the embodiments disclosed herein. The integrated circuit device assembly 700 includes a number of components disposed on a circuit board 702 (which may be a motherboard, system board, mainboard, etc.). The integrated circuit device assembly 700 includes components disposed on a first face 740 of the circuit board 702 and an opposing second face 742 of the circuit board 702; generally, components may be disposed on one or both faces 740 and 742.

In some embodiments, the circuit board 702 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 702. In other embodiments, the circuit board 702 may be a non-PCB substrate. The integrated circuit device assembly 700 illustrated in FIG. 7 includes a package-on-interposer structure 736 coupled to the first face 740 of the circuit board 702 by coupling components 716. The coupling components 716 may electrically and mechanically couple the package-on-interposer structure 736 to the circuit board 702, and may include solder balls (as shown in FIG. 7), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 736 may include an integrated circuit component 720 coupled to an interposer 704 by coupling components 718. The coupling components 718 may take any suitable form for the application, such as the forms discussed above with reference to the coupling components 716. Although a single integrated circuit component 720 is shown in FIG. 7, multiple integrated circuit components may be coupled to the interposer 704; indeed, additional interposers may be coupled to the interposer 704. The interposer 704 may provide an intervening substrate used to bridge the circuit board 702 and the integrated circuit component 720.

The integrated circuit component 720 may be a packaged or unpacked integrated circuit product that includes one or more integrated circuit dies (e.g., the die 102 of FIG. 1, the integrated circuit device 600 of FIG. 6) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 720, a single monolithic integrated circuit die comprises solder bumps attached to contacts on the die. The solder bumps allow the die to be directly attached to the interposer 704. The integrated circuit component 720 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 720 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 720 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 720 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 704 may spread connections to a wider pitch or reroute a connection to a different connection. For example, the interposer 704 may couple the integrated circuit component 720 to a set of ball grid array (BGA) conductive contacts of the coupling components 716 for coupling to the circuit board 702. In the embodiment illustrated in FIG. 7, the integrated circuit component 720 and the circuit board 702 are attached to opposing sides of the interposer 704; in other embodiments, the integrated circuit component 720 and the circuit board 702 may be attached to a same side of the interposer 704. In some embodiments, three or more components may be interconnected by way of the interposer 704.

In some embodiments, the interposer 704 may be formed as a PCB, including multiple metal layers separated from one another by layers of dielectric material and interconnected by electrically conductive vias. In some embodiments, the interposer 704 may be formed of an epoxy resin, a fiberglass-reinforced epoxy resin, an epoxy resin with inorganic fillers, a ceramic material, or a polymer material such as polyimide. In some embodiments, the interposer 704 may be formed of alternate rigid or flexible materials that may include the same materials described above for use in a semiconductor substrate, such as silicon, germanium, and other group III-V and group IV materials. The interposer 704 may include metal interconnects 708 and vias 710, including but not limited to through hole vias 710-1 (that extend from a first face 750 of the interposer 704 to a second face 754 of the interposer 704), blind vias 710-2 (that extend from the first or second faces 750 or 754 of the interposer 704 to an internal metal layer), and buried vias 710-3 (that connect internal metal layers).

In some embodiments, the interposer 704 can comprise a silicon interposer. Through silicon vias (TSV) extending through the silicon interposer can connect connections on a first face of a silicon interposer to an opposing second face of the silicon interposer. In some embodiments, an interposer 704 comprising a silicon interposer can further comprise one or more routing layers to route connections on a first face of the interposer 704 to an opposing second face of the interposer 704.

The interposer 704 may further include embedded devices 714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 704. The package-on-interposer structure 736 may take the form of any of the package-on-interposer structures known in the art. In embodiments where the interposer is a non-printed circuit board

The integrated circuit device assembly 700 may include an integrated circuit component 724 coupled to the first face 740 of the circuit board 702 by coupling components 722. The coupling components 722 may take the form of any of the embodiments discussed above with reference to the coupling components 716, and the integrated circuit component 724 may take the form of any of the embodiments discussed above with reference to the integrated circuit component 720.

The integrated circuit device assembly 700 illustrated in FIG. 7 includes a package-on-package structure 734 coupled to the second face 742 of the circuit board 702 by coupling components 728. The package-on-package structure 734 may include an integrated circuit component 726 and an integrated circuit component 732 coupled together by coupling components 730 such that the integrated circuit component 726 is disposed between the circuit board 702 and the integrated circuit component 732. The coupling components 728 and 730 may take the form of any of the embodiments of the coupling components 716 discussed above, and the integrated circuit components 726 and 732 may take the form of any of the embodiments of the integrated circuit component 720 discussed above. The package-on-package structure 734 may be configured in accordance with any of the package-on-package structures known in the art.

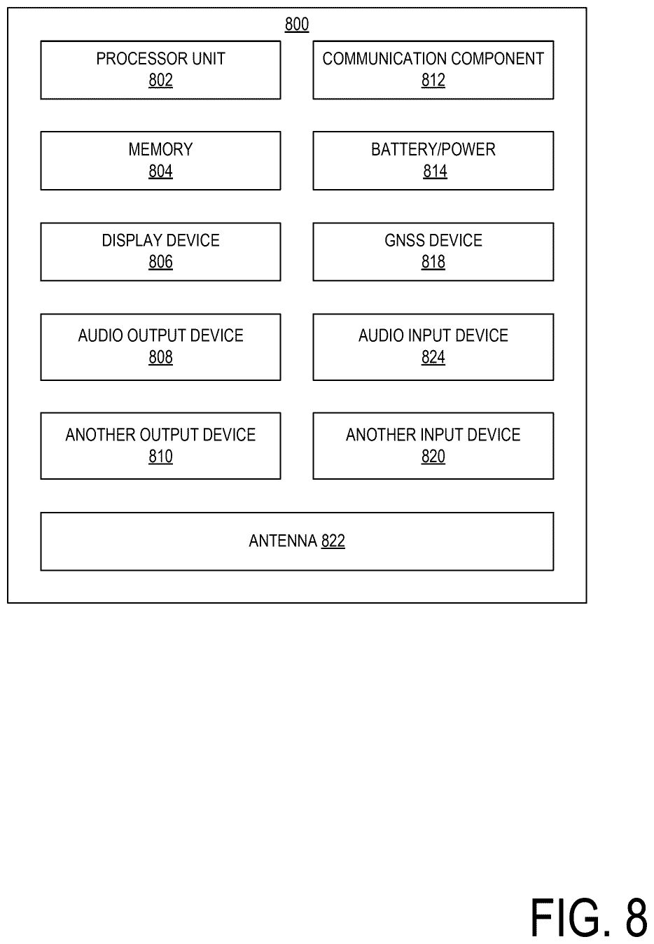

FIG. 8 is a block diagram of an example electrical device 800 that may include one or more of the embodiments disclosed herein. For example, any suitable ones of the components of the electrical device 800 may include one or more of the integrated circuit device assemblies 700, integrated circuit components 720, integrated circuit devices 600, or integrated circuit dies 102 disclosed herein. A number of components are illustrated in FIG. 8 as included in the electrical device 800, but any one or more of these components may be omitted or duplicated, as suitable for the application. In some embodiments, some or all of the components included in the electrical device 800 may be attached to one or more motherboards mainboards, or system boards. In some embodiments, one or more of these components are fabricated onto a single system-on-a-chip (SoC) die.

Additionally, in various embodiments, the electrical device 800 may not include one or more of the components illustrated in FIG. 8, but the electrical device 800 may include interface circuitry for coupling to the one or more components. For example, the electrical device 800 may not include a display device 806, but may include display device interface circuitry (e.g., a connector and driver circuitry) to which a display device 806 may be coupled. In another set of examples, the electrical device 800 may not include an audio input device 824 or an audio output device 808, but may include audio input or output device interface circuitry (e.g., connectors and supporting circuitry) to which an audio input device 824 or audio output device 808 may be coupled.

The electrical device 800 may include one or more processor units 802 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 802 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 800 may include a memory 804, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 804 may include memory that is located on the same integrated circuit die as the processor unit 802. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 800 can comprise one or more processor units 802 that are heterogeneous or asymmetric to another processor unit 802 in the electrical device 800. There can be a variety of differences between the processing units 802 in a system in terms of a spectrum of metrics of merit including architectural, microarchitectural, thermal, power consumption characteristics, and the like. These differences can effectively manifest themselves as asymmetry and heterogeneity among the processor units 802 in the electrical device 800.

In some embodiments, the electrical device 800 may include a communication component 812 (e.g., one or more communication components). For example, the communication component 812 can manage wireless communications for the transfer of data to and from the electrical device 800. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 812 may operate in accordance with other wireless protocols in other embodiments. The electrical device 800 may include an antenna 822 to facilitate wireless communications and/or to receive other wireless communications (such as AM or FM radio transmissions).

In some embodiments, the communication component 812 may manage wired communications, such as electrical, optical, or any other suitable communication protocols (e.g., IEEE 802.3 Ethernet standards). As noted above, the communication component 812 may include multiple communication components. For instance, a first communication component 812 may be dedicated to shorter-range wireless communications such as Wi-Fi or Bluetooth, and a second communication component 812 may be dedicated to longer-range wireless communications such as global positioning system (GPS), EDGE, GPRS, CDMA, WiMAX, LTE, EV-DO, or others. In some embodiments, a first communication component 812 may be dedicated to wireless communications, and a second communication component 812 may be dedicated to wired communications.

The electrical device 800 may include battery/power circuitry 814. The battery/power circuitry 814 may include one or more energy storage devices (e.g., batteries or capacitors) and/or circuitry for coupling components of the electrical device 800 to an energy source separate from the electrical device 800 (e.g., AC line power).

The electrical device 800 may include a display device 806 (or corresponding interface circuitry, as discussed above). The display device 806 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 800 may include an audio output device 808 (or corresponding interface circuitry, as discussed above). The audio output device 808 may include any embedded or wired or wirelessly connected external device that generates an audible indicator, such speakers, headsets, or earbuds.

The electrical device 800 may include an audio input device 824 (or corresponding interface circuitry, as discussed above). The audio input device 824 may include any embedded or wired or wirelessly connected device that generates a signal representative of a sound, such as microphones, microphone arrays, or digital instruments (e.g., instruments having a musical instrument digital interface (MIDI) output). The electrical device 800 may include a Global Navigation Satellite System (GNSS) device 818 (or corresponding interface circuitry, as discussed above), such as a Global Positioning System (GPS) device. The GNSS device 818 may be in communication with a satellite-based system and may determine a geolocation of the electrical device 800 based on information received from one or more GNSS satellites, as known in the art.

The electrical device 800 may include another output device 810 (or corresponding interface circuitry, as discussed above). Examples of the other output device 810 may include an audio codec, a video codec, a printer, a wired or wireless transmitter for providing information to other devices, or an additional storage device.

The electrical device 800 may include another input device 820 (or corresponding interface circuitry, as discussed above). Examples of the other input device 820 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 800 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 800 may be any other electronic device that processes data. In some embodiments, the electrical device 800 may comprise multiple discrete physical components. Given the range of devices that the electrical device 800 can be manifested as in various embodiments, in some embodiments, the electrical device 800 can be referred to as a computing device or a computing system.

Applications that depend on extremely high-performance computing include those that are expected to perform on the order of one zettaflops (10²¹ floating point operations per second). These applications may be referred to as zetta-scale performance applications. Non-limiting examples of zetta-scale performance applications include supercomputing, autonomous driving, and machine learning. Realizing platforms capable of zetta-scale performance presents technological challenges and packaging and system-level architecture innovations are expected to be developed to realize this level of performance. Proposed technical solutions include system-level heterogeneous integration of compute, I/O, memory, power management, and thermal management components. Some available high-performance computing solutions include implementing system-level architectures on a wafer (also referred to as wafer-level system integration, or a wafer-level solution). However, wafer-level system integration incurs several technical challenges. As may be appreciated, wafer-level system integration has packages that are limited in size by the diameter of a wafer. In addition, wafer-level system integration puts one entire system on one wafer. Accordingly, resolving yield issues for wafer-level solutions may become very challenging. Embodiments of the present disclosure may be implemented in zetta-scale applications, which might not utilize wafer-level system integration.

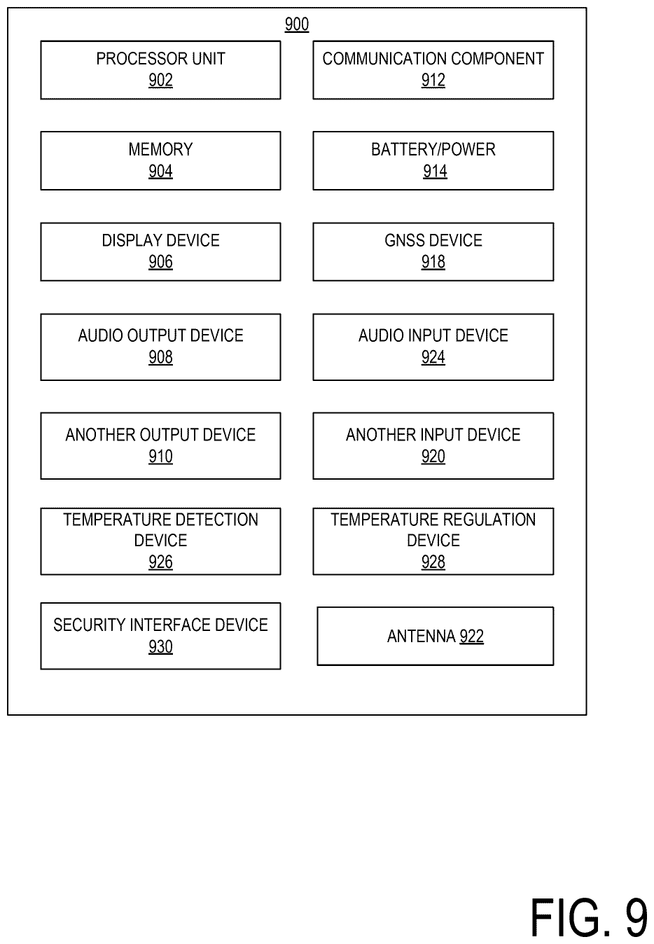

FIG. 9 is a block diagram of an example zetta-scale device 900 that may include any of the embodiments disclosed herein. In some instances, the example device 900 may represent a zetta-unit of compute (Zuoc). The example device 900 includes a processor unit 902, which may be a processor unit capable of performance on the zetta-scale, i.e., capable of performing at least 10²¹ floating point operations per second. The example device 900 also includes memory 904, which may be implemented in a similar manner as the memory 804 described above. In particular embodiments, the memory 904 may be implemented using arrays of commodity memory modules as described herein. The example device 900 also includes a display device 906, audio output device 908, another output device 910, communication component 912, battery/power circuitry 914, GNSS device 918, audio input device 924, another input device 920, and antenna 922, each of which may be implemented in a similar manner as the same respective components of the electrical device 800 described above.

The example device 900 further includes a temperature detection device 926 and a temperature regulation device 928. The temperature detection device 926 may include any device capable of determining temperatures of the computing device 900 or of any individual components therein (e.g., temperatures of the processing device 902 or of the memory 904). In various embodiments, the temperature detection device may be configured to determine temperatures of an object (e.g., the computing device 900, components of the computing device 900, devices coupled to the computing device, etc.), temperatures of an environment (e.g., a data center that includes, is controlled by, or otherwise associated with the computing device 900), and so on. The temperature detection device 926 may include one or more temperature sensors. Different temperature sensors of the temperature detection device 926 may have different locations within and around the computing device 900. A temperature sensor may generate data (e.g., digital data) representing detected temperatures and provide the data to another device, e.g., to the temperature regulation device 928, the processing device 902, the memory 904, etc. In some embodiments, a temperature sensor of the temperature detection device 926 may be turned on or off, e.g., by the processing device 902 or an external system. The temperature sensor detects temperatures when it is on and does not detect temperatures when it is off. In other embodiments, a temperature sensor of the temperature detection device 926 may detect temperatures continuously and automatically or detect temperatures at predefined times or at times triggered by an event associated with the computing device 900 or any components therein.

The temperature regulation device 928 may include any device configured to change (e.g., decrease) temperatures, e.g., based on one or more target temperatures and/or based on temperature measurements performed by the temperature detection device 926. A target temperature may be a preferred temperature. A target temperature may depend on a setting in which the computing device 900 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 900 can be different. In some embodiments, cooling provided by the temperature regulation device 928 may be a multi-stage process with temperatures ranging from room temperature to 4K or lower.

In some embodiments, the temperature regulation device 928 may include one or more cooling devices. Different cooling device may have different locations within and around the computing device 900. A cooling device of the temperature regulation device 928 may be associated with one or more temperature sensors of the temperature detection device 926 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 900 is satisfied. In response to determining that one or more temperature-related condition associated with the temperature of the computing device 900 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 928 may operate with various cooling mechanisms, such as evaporation cooling, radiation cooling, conduction cooling, convection cooling, other cooling mechanisms, or any combination thereof. A cooling device of the temperature regulation device 928 may include a cooling agent, such as a water, oil, liquid nitrogen, liquid helium, etc. In some embodiments, the temperature regulation device 928 may be, for example, a dilution refrigerator, a helium-3 refrigerator, or a liquid helium refrigerator. In some embodiments, the temperature regulation device 928 or any portions thereof (e.g., one or more of the individual cooling devices) may be connected to the computing device 900 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 900 (or components thereof) can be reduced, while the computing efficiency may be improved. For example, when the computing device 900 (or components thereof) operates at lower temperatures, energy dissipation (e.g., heat dissipation) may be reduced. Further, energy consumed by semiconductor components (e.g., energy needed for switching transistors of any of the components of the computing device 900) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy correlates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The example device 900 further includes a security interface device 930. The security interface device 930 may include any device that provides security features for the computing device 900 or for any individual components therein (e.g., for the processing device 902 or for the memory 904). Examples of security features may include authorization, access to digital certificates, access to items in keychains, etc. Examples of the security interface device 930 may include a software firewall, a hardware firewall, an antivirus, a content filtering device, or an intrusion detection device.

The computing device 900 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 900 may be any other electronic device that processes data.

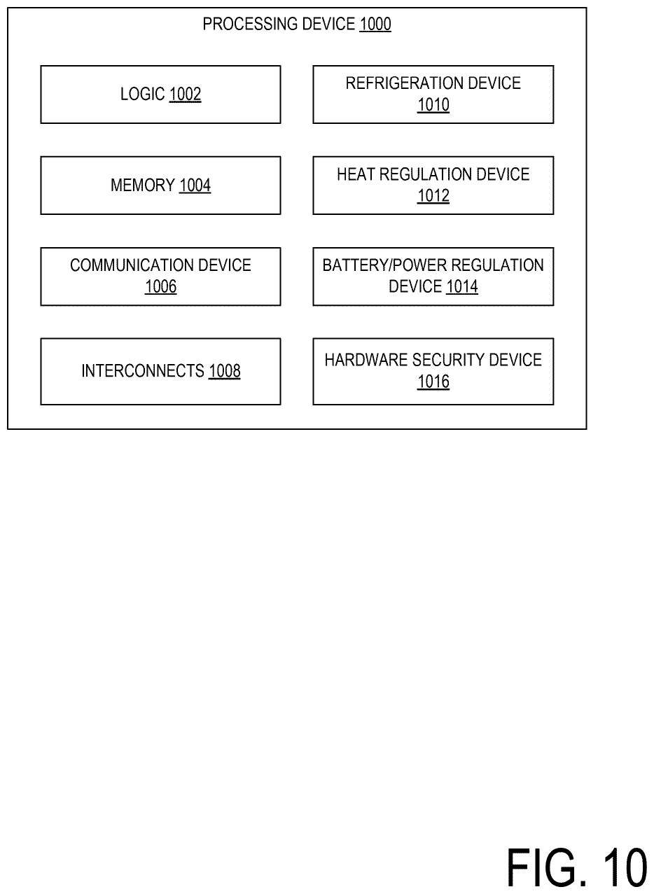

FIG. 10 is a block diagram of an example zetta-scale processing device 1000 that may include any of the embodiments disclosed herein. In some instances, the example device 1000 may represent a zetta-unit of compute (Zuoc). The example zetta-scale processing device 1000 includes memory 1002, logic 1004, a communication device 1006, interconnects 1008 (including metallization and redistribution layers), a refrigeration device 1010, a heat regulation device 1012, a battery/power regulation device 1014, and a hardware security device 1016.

A number of components are illustrated in FIG. 10 as included in the processing device 1000, but any one or more of these components may be omitted or duplicated, as suitable for the application. In some embodiments, some or all of the components included in the processing device 1000 may be attached to one or more motherboards. In some embodiments, some or all of these components are fabricated on a single SoC die or coupled to a single support structure, e.g., to a single carrier substrate. Additionally, in various embodiments, the processing device 1000 may not include one or more of the components illustrated in FIG. 10, but the processing device 1000 may include interface circuitry for coupling to the one or more components. For example, the processing device 1000 may not include a memory 1004, but may include device interface circuitry (e.g., a connector and driver circuitry) to which a memory 1004 may be coupled.

The processing device 1000 may include logic circuitry 1002 (e.g., one or more circuits configured to implement logic/compute functionality). Examples of such circuits include ICs implementing one or more of input/output (I/O) functions, arithmetic operations, pipelining of data, etc. In some embodiments, the logic circuitry 1002 may include one or more circuits responsible for read/write operations with respect to the data stored in the memory 1004. To that end, the logic circuitry 1002 may include one or more I/O ICs configured to control access to data stored in the memory 1004. In certain embodiments, the logic circuitry 1002 and the memory circuitry 1004 may together be capable of 10²¹ floating point operations per second.

In some embodiments, the logic circuitry 1002 may include one or more high-performance compute dies, configured to perform various operations with respect to data stored in the memory 1004 (e.g., arithmetic and logic operations, pipelining of data from one or more memory dies of the memory 1004, and possibly also data from external devices/chips). In some embodiments, the logic circuitry 1002 may be configured to only control I/O access to data but not perform any operations on the data. In some embodiments, the logic circuitry 1002 may implement ICs configured to implement I/O control of data stored in the memory 1004, assemble data from the memory 1004 for transport (e.g., transport over a central bus) to devices/chips that are either internal or external to the processing device 1000, etc. In some embodiments, the logic circuitry 1002 may not be configured to perform any operations on the data besides I/O and assembling for transport to the memory 1004.

The processing device 1000 may include a memory 1004, which may include one or more ICs configure to implement memory circuitry (e.g., ICs implementing one or more of memory devices, memory arrays, control logic configured to control the memory devices and arrays, etc.). In some embodiments, the memory 1004 may be implemented substantially as described above with reference to the memory 904. In some embodiments, the memory 1004 may be a designated device configured to provide storage functionality for the components of the processing device 1000 (i.e., local), while the memory 904 may be configured to provide system-level storage functionality for the entire computing device 1000 (i.e., global). The memory 1004 may be implemented as an array of multiple memory modules as described herein.

In some embodiments, the memory 1004 may include a flat memory (also sometimes referred to as a “flat hierarchy memory” or a “linear memory”) and, therefore, may also be referred to as a “basin memory.” As known in the art, a flat memory or a linear memory refers to a memory addressing paradigm in which memory may appear to the program as a single contiguous address space, where a processor can directly and linearly address all of the available memory locations without having to resort to memory segmentation or paging schemes. Thus, the memory implemented in the memory 1004 may be a memory that is not divided into hierarchical layer or levels in terms of access of its data.

In some embodiments, the memory 1004 may include a hierarchical memory. In this context, hierarchical memory refers to the concept of computer architecture where computer storage is separated into a hierarchy based on features of memory such as response time, complexity, capacity, performance, and controlling technology. Designing for high performance may require considering the restrictions of the memory hierarchy, i.e., the size and capabilities of each component. With hierarchical memory, each of the various memory components can be viewed as part of a hierarchy of memories (m1, m2, . . . , mn) in which each member mi is typically smaller and faster than the next highest member mi+1 of the hierarchy. To limit waiting by higher levels, a lower level of a hierarchical memory structure may respond by filling a buffer and then signaling for activating the transfer. For example, in some embodiments, the hierarchical memory implemented in the memory 1004 may be separated into four major storage levels: 1) internal storage (e.g., processor registers and cache), 2) main memory (e.g., the system RAM and controller cards), and 3) on-line mass storage (e.g., secondary storage), and 4) off-line bulk storage (e.g., tertiary, and off-line storage). However, as the number of levels in the memory hierarchy and the performance at each level has increased over time and is likely to continue to increase in the future, this example hierarchical division provides only one non-limiting example of how the memory 04 may be arranged.

The processing device 1000 may include a communication device 1006, which may be implemented substantially as described above with reference to the communication chip 906. In some embodiments, the communication device 1006 may be a designated device configured to provide communication functionality for the components of the processing device 1000 (i.e., local), while the communication chip 906 may be configured to provide system-level communication functionality for the entire computing device 900 (i.e., global).

The processing device 1000 may include interconnects 1008, which may include any element or device that includes an electrically conductive material for providing electrical connectivity to one or more components of, or associated with, a processing device 1000 or/and between various such components. Examples of the interconnects 1008 include conductive lines/wires (also sometimes referred to as “lines” or “metal lines” or “trenches”) and conductive vias (also sometimes referred to as “vias” or “metal vias”), metallization stacks, redistribution layers, metal-insulator-metal (MIM) structures, etc.

The processing device 1000 may include a temperature detection device 1010 which may be implemented substantially as described above with reference to the temperature detection device 926 of FIG. 9 but configured to determine temperatures on a more local scale, i.e., of the processing device 1000 of components thereof. In some embodiments, the temperature detection device 1010 may be a designated device configured to provide temperature detection functionality for the components of the processing device 1000 (i.e., local), while the temperature detection device 926 may be configured to provide system-level temperature detection functionality for the entire computing device 900 (i.e., global).

The processing device 1000 may include a temperature regulation device 1012 which may be implemented substantially as described above with reference to the temperature regulation device 928 of FIG. 9 but configured to regulate temperatures on a more local scale, i.e., of the processing device 1000 of components thereof. In some embodiments, the temperature regulation device 1012 may be a designated device configured to provide temperature regulation functionality for the components of the processing device 1000 (i.e., local), while the temperature regulation device 928 may be configured to provide system-level temperature regulation functionality for the entire computing device 900 (i.e., global).

The processing device 1000 may include a battery/power circuitry 1014 which may be implemented substantially as described above with reference to the battery/power circuitry 910 of FIG. 9. In some embodiments, the battery/power circuitry 1014 may be a designated device configured to provide battery/power functionality for the components of the processing device 1000 (i.e., local), while the battery/power circuitry 910 may be configured to provide system-level battery/power functionality for the entire computing device 900 (i.e., global).

The processing device 1000 may include a hardware security device 1016 which may be implemented substantially as described above with reference to the security interface device 924 of FIG. 9. In some embodiments, the hardware security device 1016 may be a physical computing device configured to safeguard and manage digital keys, perform encryption and decryption functions for digital signatures, authentication, and other cryptographic functions. In some embodiments, the hardware security device 1016 may include one or more secure cryptoprocessors chips.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is an integrated circuit device comprising: a logic die comprising processor circuitry; and a memory die coupled to the logic die, the memory die comprising: a first memory module comprising a first memory bank and first control circuitry; a second memory module comprising a second memory bank and second control circuitry; and a scribe line on a surface of the memory die between the first memory module and the second memory module.

Example 2 includes the subject matter of Example 1, wherein the first memory module is not electrically connected to the second memory module.

Example 3 includes the subject matter of Example 1 or 2, wherein each memory module comprises through silicon vias (TSVs) to electrically connect a top side of the memory module and a bottom side of the memory module.

Example 4 includes the subject matter of Example 3, wherein the TSVs electrically connect the memory bank and control circuitry of the memory module to the top side and the bottom side of the memory module.

Example 5 includes the subject matter of Example 3 or 4, wherein the TSVs form a grid pattern on the memory module.

Example 6 includes the subject matter of any one of Examples 1-5, wherein each memory module comprises a plurality of memory banks and a plurality of control circuitries, each control circuitry to control a respective memory bank of the memory module.

Example 7 includes the subject matter of any one of Examples 1-6, wherein the memory die is coupled to a top side of the logic die.

Example 8 includes the subject matter of any one of Examples 1-6, wherein the memory die is coupled to a bottom side of the logic die.

Example 9 includes the subject matter of any one of Examples 1-8, wherein the memory die and the logic die are coupled via an interposer comprising circuitry to interconnect the first die and the second die.

Example 10 includes the subject matter of any one of Examples 1-9, wherein the memory die is a first memory die, and the device further comprises a second memory die coupled to the first die and to the second die.

Example 11 is an integrated circuit package comprising the integrated circuit device of any one of Examples 1-10 and a package substrate coupled to the integrated circuit device.

Example 12 includes the subject matter of Example 11, wherein the package substrate comprises circuitry to interconnect the integrated circuit device to a main circuit board.

Example 13 is a system comprising a main circuit board and the integrated circuit package of Example 11 or 12 coupled to the main circuit board.

Example 14 is a method of manufacturing integrated circuit devices comprising: determining that an integrated circuit device is to include a memory die with a first memory capacity; dividing a wafer comprising a plurality of memory modules to yield a memory die comprising a subset of the memory modules, wherein the subset of memory modules of the memory die has a memory capacity that is the same as the first memory capacity; and attaching the memory die to the integrated circuit device.

Example 15 includes the subject matter of Example 14, wherein the memory die comprises: a first memory module comprising a first memory bank and first control circuitry; a second memory module comprising a second memory bank and second control circuitry; and a scribe line on a surface of the memory die between the first memory module and the second memory module.

Example 16 includes the subject matter of Example 14 or 15, wherein memory modules of the memory die are not electrically connected with one another.

Example 17 includes the subject matter of any one of Examples 14-16, wherein each memory module comprises through silicon vias (TSVs) to electrically connect a top side of the memory module and a bottom side of the memory module.

Example 18 includes the subject matter of Example 17, wherein the TSVs electrically connect the memory bank and control circuitry of the memory module to the top side and the bottom side of the memory module.

Example 19 includes the subject matter of Example 17, wherein the TSVs form a grid pattern on the memory module.

Example 20 includes the subject matter of any one of Examples 14-19, wherein the integrated circuit device is a first integrated circuit device, the memory die is a first memory die comprising a first subset of memory modules, and the method further comprises: determining that a second integrated circuit device is to include a memory die with a second memory capacity; further dividing the wafer to yield a second memory die comprising a second subset of the memory modules, wherein the second subset of memory modules of the memory die has a memory capacity that is the same as the second memory capacity; and attaching the second memory die to the second integrated circuit device.

Example 21 includes the subject matter of Example 20, wherein the first memory capacity and the second memory capacity are the same.

Example 22 includes the subject matter of Example 20, wherein the first memory capacity and the second memory capacity are different.

Example 23 includes the subject matter of any one of Examples 20-22, wherein the second memory die comprises: a first memory module comprising a first memory bank and first control circuitry; a second memory module comprising a second memory bank and second control circuitry; and a scribe line on a surface of the memory die between the first memory module and the second memory module.

Example 24 includes the subject matter of any one of Examples 20-23, wherein memory modules of the second memory die are not electrically connected with one another.

Example 25 includes the subject matter of any one of Examples 20-24, wherein each memory module comprises through silicon vias (TSVs) to electrically connect a top side of the memory module and a bottom side of the memory module.

Example 26 includes an apparatus comprising: a three-dimensional integrated circuit device comprising: a logic die comprising processor circuitry; and a memory die coupled to the logic die, the memory die comprising a plurality of memory modules, each memory module comprising a memory bank and control circuitry for the memory bank, the memory die further comprising a scribe line on a surface of the memory die between the first memory module and the second memory module.

Example 27 includes the subject matter of Example 26, wherein the memory modules of the memory die are not electrically connected with one another.

Example 28 includes the subject matter of any one of Examples 26-27, wherein each memory module comprises through silicon vias (TSVs) to electrically connect a top side of the memory module and a bottom side of the memory module.

Example 28.1 includes the subject matter of Example 28, wherein the TSVs electrically connect the memory bank and control circuitry of the memory module to the top side and the bottom side of the memory module.

Example 28.2 includes the subject matter of Example 28, wherein the TSVs form a grid pattern on the memory module.

Example 29 includes the subject matter of any one of Examples 26-28.2, wherein each memory module comprises a plurality of memory banks and a plurality of control circuitries, each control circuitry to control a respective memory bank of the memory module.

Example 30 includes the subject matter of any one of Examples 26-29, further comprising a package substrate coupled to the three-dimensional integrated circuit device, the package substrate comprising circuitry to interconnect the three-dimensional integrated circuit device to other circuitry.

Example 31 includes the subject matter of Example 30, further comprising a main circuit board coupled to the package substrate.

Example 32 includes the subject matter of any one of Examples 26-31, wherein the memory die comprises: a first memory module comprising a first memory bank and first control circuitry; and a second memory module comprising a second memory bank and second control circuitry.

Example 33 includes the subject matter of any one of Examples 26-32, wherein the memory die is coupled to a top side of the logic die.

Example 34 includes the subject matter of any one of Examples 26-32, wherein the memory die is coupled to a bottom side of the logic die.

Example 35 includes the subject matter of any one of Examples 26-34, wherein the memory die and the logic die are coupled via an interposer comprising circuitry to interconnect the first die and the second die.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature. Further, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An integrated circuit device comprising:
a logic die comprising processor circuitry; and
a memory die coupled to the logic die, the memory die comprising:
a first memory module comprising a first memory bank and first control circuitry;
a second memory module comprising a second memory bank and second control circuitry; and
a scribe line on a surface of the memory die between the first memory module and the second memory module.

2. The integrated circuit device of claim 1, wherein the first memory module is not electrically connected to the second memory module.

3. The integrated circuit device of claim 1, wherein each memory module comprises through silicon vias (TSVs) to electrically connect a top side of the memory module and a bottom side of the memory module.

4. The integrated circuit device of claim 3, wherein the TSVs electrically connect the memory bank and control circuitry of the memory module to the top side and the bottom side of the memory module.

5. The integrated circuit device of claim 3, wherein the TSVs form a grid pattern on the memory module.

6. The integrated circuit device of claim 1, wherein each memory module comprises a plurality of memory banks and a plurality of control circuitries, each control circuitry to control a respective memory bank of the memory module.

7. The integrated circuit device of claim 1, wherein the memory die is coupled to a top side of the logic die.

8. The integrated circuit device of claim 1, wherein the memory die is coupled to a bottom side of the logic die.

9. The integrated circuit device of claim 1, wherein the memory die and the logic die are coupled via an interposer comprising circuitry to interconnect the first die and the second die.

10. The integrated circuit device of claim 1, wherein the memory die is a first memory die, and the device further comprises a second memory die coupled to the first die and to the second die.

11. An apparatus comprising:
a three-dimensional integrated circuit device comprising:
a logic die comprising processor circuitry; and
a memory die coupled to the logic die, the memory die comprising a plurality of memory modules, each memory module comprising a memory bank and control circuitry for the memory bank, the memory die further comprising a scribe line on a surface of the memory die between the first memory module and the second memory module.

12. The apparatus of claim 11, wherein the memory modules of the memory die are not electrically connected with one another.

13. The apparatus of claim 11, wherein each memory module comprises through silicon vias (TSVs) to electrically connect a top side of the memory module and a bottom side of the memory module.

14. The apparatus of claim 11, wherein each memory module comprises a plurality of memory banks and a plurality of control circuitries, each control circuitry to control a respective memory bank of the memory module.

15. The apparatus of claim 11, further comprising a package substrate coupled to the three-dimensional integrated circuit device, the package substrate comprising circuitry to interconnect the three-dimensional integrated circuit device to other circuitry.

16. A method of manufacturing integrated circuit devices comprising:
determining that an integrated circuit device is to include a memory die with a first memory capacity;
dividing a wafer comprising a plurality of memory modules to yield a memory die comprising a subset of the memory modules, wherein the subset of memory modules of the memory die has a memory capacity that is the same as the first memory capacity; and
attaching the memory die to the integrated circuit device.

17. The method of claim 16, wherein the memory modules of the memory die are not electrically connected with one another.

18. The method of claim 16, wherein the integrated circuit device is a first integrated circuit device, the memory die is a first memory die comprising a first subset of memory modules, and the method further comprises:
determining that a second integrated circuit device is to include a memory die with a second memory capacity;
further dividing the wafer to yield a second memory die comprising a second subset of the memory modules, wherein the second subset of memory modules of the memory die has a memory capacity that is the same as the second memory capacity; and
attaching the second memory die to the second integrated circuit device.

19. The method of claim 18, wherein the first memory capacity and the second memory capacity are the same.

20. The method of claim 18, wherein the first memory capacity and the second memory capacity are different.
